(19) United States
(12) Patent Application Publication
(10) Pub. No.: US 2010/0061065 A1
(43) Pub. Date: Mar. 11, 2010

(54) ELECTRONIC DEVICE

(75) Inventor: Shinya HAYASHIYAMA, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/413,261

(22) Filed: Mar. 27, 2009

(30) Foreign Application Priority Data
Sep. 10, 2008 (JP) 2008-232608

(51) Int. Cl. H05K 5/00

(52) U.S. Cl. 361/752; 361/768

(57) ABSTRACT

According to one embodiment, an electronic device includes a housing, a circuit board in the housing, a plurality of surface-mountable electronic components, and a reinforcing frame. The circuit board has a first surface and a second surface on a reverse side of the first surface. The surface-mountable electronic components, each having a surface on which bumps are arranged, are mounted on the first surface via the bumps. The reinforcing frame is arranged on the second surface such that it passes through portions corresponding to positions of bumps located at at least four corners of the bumps arranged on the surface of each of the surface-mountable electronic components mounted on the first surface.

### CROSS-REFERENCE TO RELATED APPLICATIONS

This application is based upon and claims the benefit of priority from Japanese Patent Application No. 2008-232608, filed Sep. 10, 2008, the entire contents of which are incorporated herein by reference.

### BACKGROUND

1. Field

One embodiment of the invention relates to an electronic device.

2. Description of the Related Art

In recent years, with an increased diversity of packaging for electronic components such as a semiconductor chip mounted on a circuit board, surface-mountable electronic components have been in widespread use. A surface-mountable electronic component does not require a lead or a pin for connection to a circuit board.

Among such surface-mountable electronic components is a ball grid array (BGA). The BGA is a leadless surface-mountable package, in which, for connection to external circuits, a plurality of electrodes (pads) are formed on the bottom thereof, and a grid of bumps such as solder balls is arranged on the pads to constitute a connection terminal. The BGA package is mounted on a circuit board through so-called reflow soldering by heating the solder balls in contact with the pads of the circuit board.

When a portable electronic device including such a circuit board is subjected to the impact of, for example, its fall, the circuit board may be deformed. In this case, stress is caused on the joints (solder joints) between the surface-mountable electronic component and the circuit board, and accordingly, the solder joints may be damaged. The circuit board is deformed substantially when the electronic device falls in the vertical direction with respect to the wiring surface of the circuit board. In such cases, especially when the electronic device falls with the side having the surface-mountable electronic component mounted thereon facing down, a large stress is placed on the solder joints, and the solder joints are more likely to be damaged.

In view of this, Japanese Patent Application Publication (KOKAI) No. 2006-210852 discloses a conventional circuit board provided with a reinforcing plate. The reinforcing plate is arranged on the back of a surface-mountable electronic component with the circuit board between them. More specifically, the reinforcing plate is arranged on a side of the circuit board opposite the side on which the surface-mountable electronic component is mounted. The reinforcing plate is larger than the bottom surface of the surface-mountable electronic component to surround the portion corresponding to where the surface-mountable electronic component is mounted (hereinafter, “mounting portion”).

In the conventional circuit board, the reinforcing plate is arranged to be shifted from a position corresponding to the mounting portion. Therefore, when an external force is applied vertically to the surface of the circuit board on which is mounted the surface-mountable electronic component, deformation occurs between the position corresponding to the mounting portion and the reinforcing plate. This causes a large stress on the solder joints and thus damages the solder joints.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary schematic diagram of the inside of the housing of the portable computer in the first embodiment;

FIG. 3 is an exemplary schematic diagram of bumps arranged in a grid on the bottom surface of a package in the first embodiment;

FIG. 4 is an exemplary schematic diagram for explaining portions on a second mounting surface corresponding to the positions of solder balls in the first embodiment;

FIG. 5 is an exemplary cross-sectional view of the housing taken along the line F1-F1 of FIG. 2 in the first embodiment;

FIG. 6 is an exemplary cross-sectional view of the housing taken along the line F2-F2 of FIG. 2 in the first embodiment;

FIG. 7 is an exemplary perspective view of a reinforcing frame according to a modification of the first embodiment;

FIG. 8 is an exemplary perspective view of a reinforcing frame according to another modification of the first embodiment; and

FIG. 9 is an exemplary schematic diagram of the inside of the housing of a portable computer according to a second embodiment of the invention.

### DETAILED DESCRIPTION

Various embodiments according to the invention will be described hereinafter with reference to the accompanying drawings. In general, according to one embodiment of the invention, an electronic device comprises a housing, a circuit board in the housing, a plurality of surface-mountable electronic components, and a reinforcing frame. The circuit board comprises a first surface and a second surface on a reverse side of the first surface. The surface-mountable electronic components, each comprising a surface on which bumps are arranged, are configured to be mounted on the first surface via the bumps. The reinforcing frame is configured to be arranged on the second surface such that the reinforcing frame passes through portions corresponding to positions of bumps located at at least four corners of the bumps arranged on the surface of each of the surface-mountable electronic components mounted on the first surface.

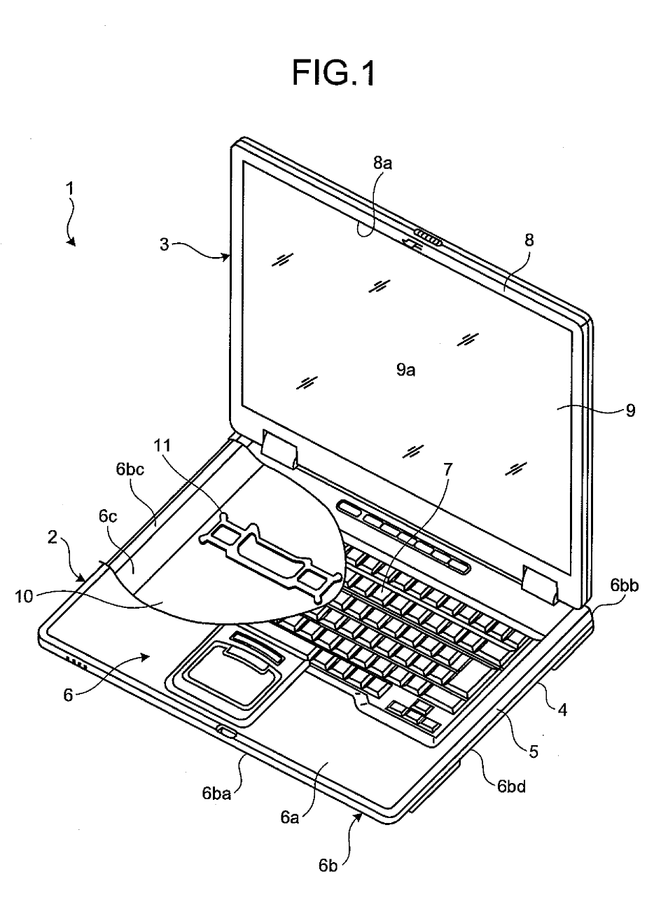

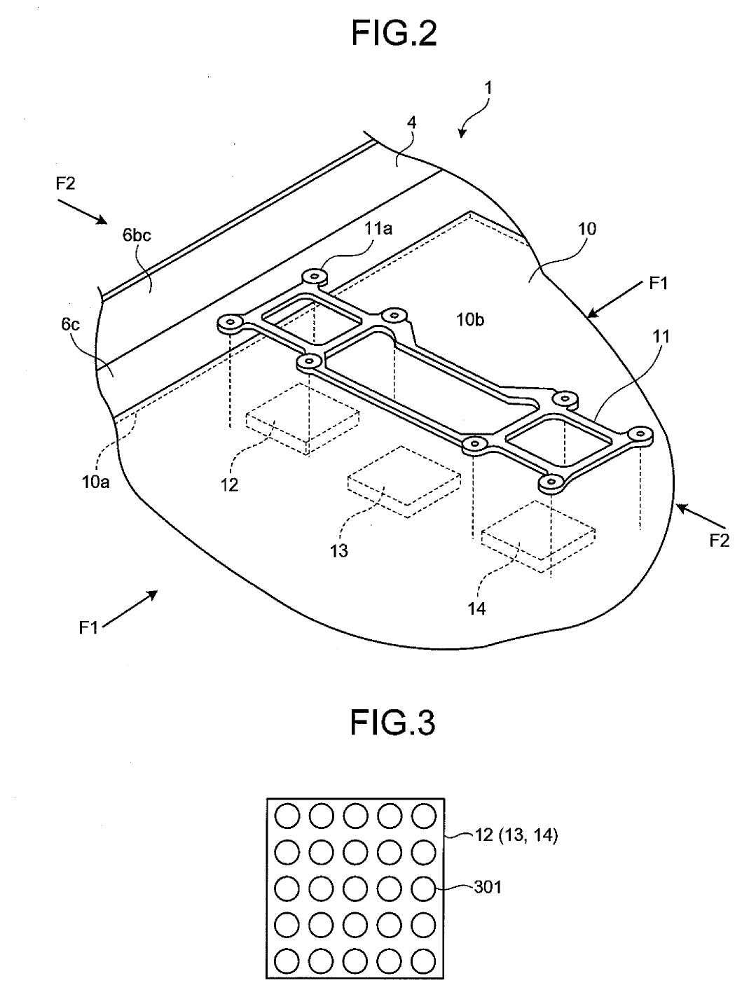

With reference to FIGS. 1 and 2, a description will be given of a configuration of a portable electronic device according to a first embodiment of the invention. In the following, the portable electronic device will be described as a portable computer such as a notebook personal computer by way of example and without limitation; however, it can be other electronic devices, such as a digital camera, a video camera and a personal digital assistant, provided with a printed circuit board having a surface-mountable electronic component mounted thereon. FIG. 1 is a perspective view of a portable computer 1 according to the first embodiment. FIG. 2 illustrates the inside of a housing 6 of the portable computer 1.

The portable computer 1 of the first embodiment comprises a main body 2 and a display module 3.

The main body 2 comprises a base 4 and a cover 5. The cover 5 is fitted on the base 4. A combination of the base 4 and the cover 5 provides the main body 2 with the housing 6 formed in a box shape.

The housing 6 has a top wall 6a, a side wall 6b, and a bottom wall 6c. Supported on the top wall 6a is a keyboard 7. The side wall 6b includes a front side wall 6ba, a rear side wall 6bb, a left side wall 6bc and a right side wall 6bd.

The display module 3 comprises a display housing 8 and a liquid crystal display (LCD) panel 9 housed in the display housing 8. The LCD panel 9 is provided with a display screen 9a. The display housing 8 has an opening 8a on its surface so that the display screen 9a is exposed to the outside thereof through the opening 8a.

The display module 3 is hingedly supported on the rear edge of the housing 6. This allows the display module 3 to rotate between a closed position and an open position. The display module 3 lies and covers over the top wall 6a in the closed position, while it stands to expose the top wall 6a in the open position.

The housing 6 houses a circuit board 10, a reinforcing frame 11, and packages 12 to 14.

The packages 12 to 14 are surface-mountable electronic components that needs neither a lead nor a pin for electrically connecting to a circuit board. The packages 12 to 14 of the first embodiment are each provided with a base having electrodes (pads) formed on the top and bottom surfaces thereof. A semiconductor chip, i.e., an electronic component mounted on the top surface of the base, is bonded to a pad by flip-chip bonding or wire bonding, and is sealed with a resin material. The pads formed on the top surface of the base, each bonded to the semiconductor chip, are electrically connected to the pads arranged in a grid on the bottom surface of the base.

A bump such as a solder ball is attached to each of the pads arranged on the bottom surface of the base, which is the bottom surface of the packages 12 to 14, to form the packages 12 to 14 as, for example, BGA packages or chip size packages (CSPs). FIG. 3 illustrates an example of solder balls arranged in a grid on the bottom surface of a package. In the first embodiment, as illustrated in FIG. 3, solder balls (bumps) 301 are arranged in a grid on the bottom surface of each of the packages 12 to 14 (the bottom surface of the base).

The “BGA package” refers herein to a leadless surface-mountable package, on the bottom surface of which the solder balls 301 are arranged in a grid by a dispenser. The BGA package is used when soldering is performed in a reflow furnace. The “CSP” refers herein to a type of semiconductor chip package that is equal in size to a chip or slightly larger than the chip.

Examples of electronic components sealed in the packages 12 to 14 include, but are not limited to, a central processing unit (CPU), a graphics processing unit (GPU), and various types of chipsets. In addition to the examples cited above, any other electronic components may be sealed in the packages 12 to 14.

The circuit board 10 has a first mounting surface 10a and a second mounting surface 10b opposite the first mounting surface 10a. The packages 12 to 14 are linearly arranged on the first mounting surface 10a. On the other hand, the reinforcing frame 11, which will be described later, is arranged on the second mounting surface 10b. In the first embodiment, it is assumed, for example, that the packages 12 to 14 are aligned in substantially a straight line on the first mounting surface 10a.

The first mounting surface 10a is the lower surface of the circuit board 10,and faces the bottom wall 6c. The packages 12 to 14 are joined to the first mounting surface 10a via the solder balls 301 attached to the pads arranged on the bottom surface of the base, i.e., the bottom surface of each of the packages 12 to 14. The packages 12 to 14 are soldered to the first mounting surface 10a through reflow soldering by heating the solder balls 301 on the bottom surfaces of the packages 12 to 14 in contact with the first mounting surface 10a.

On the other hand, the second mounting surface 10b is the upper surface of the circuit board 10, and is the rear of the first mounting surface 10a. The second mounting surface 10b faces the top wall 6a. As described above, the reinforcing frame 11, which will be described later, is arranged on the second mounting surface 10b.

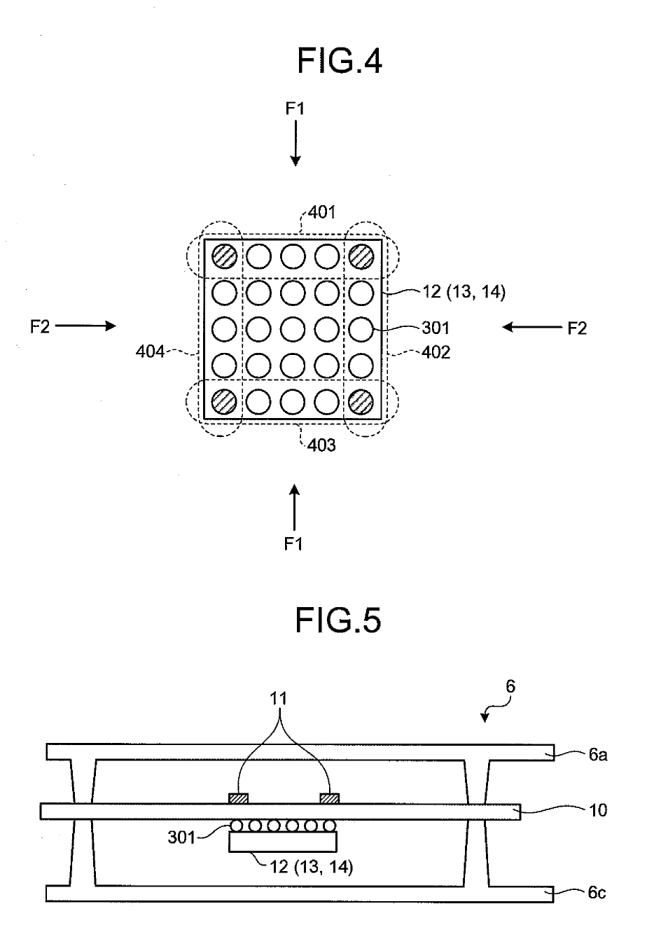

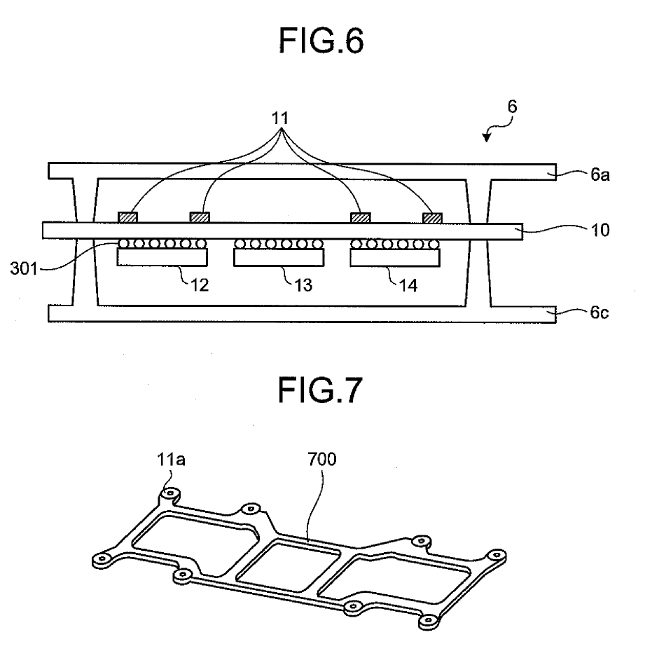

With reference to FIGS. 4 to 6, a description will be given of a specific configuration of the reinforcing frame 11 and how to arrange it. FIG. 4 is a schematic diagram for explaining portions on the second mounting surface 10b corresponding to the positions of the solder balls 301. FIG. 5 is a cross-sectional view of the housing 6 taken along the line F1-F1 of FIG. 2. FIG. 6 is a cross-sectional view of the housing 6 taken along the line F2-F2 of FIG. 2.

As illustrated in FIG. 4, the reinforcing frame 11 is arranged such that it passes through portions on the second mounting surface 10b corresponding to the positions of at least four of the solder balls 301 arranged on the bottom surface of the package 12 (13, 14). The four solder balls (indicated by hatching) are located at four corners of a grid of the solder balls 301. With this arrangement, the reinforcing frame 11 reinforces the direct backs of those most likely to be damaged by, for example, a crack or suffered from poor connection due to deformation of the circuit board 10 among the solder balls 301 arranged in a grid on the bottom surface of the package 12 (13, 14).

In the first embodiment, the reinforcing frame 11 is arranged such that it passes through portions on the second mounting surface lob corresponding to the positions of solder balls 401 and 403 among the solder balls 301 arranged in a grid on the bottom surface of the package 12 (13, 14). As illustrated in FIG. 4, the solder balls 401 and 403 are located at the outermost periphery on two opposite sides of the grid of the solder balls 301. The two opposite sides extend in the direction in which the packages 12 to 14 are aligned in substantially a straight line.

Further, in the first embodiment, the reinforcing frame 11 is arranged such that it passes through portions on the second mounting surface 10b corresponding to the positions of solder balls 402 and 404 among the solder balls 301 arranged in a grid on the bottom surface of each of the packages 12 and 14 on the respective sides. As illustrated in FIG. 4, the solder balls 402 and 404 are also located at the outermost periphery.

Thus, as illustrated in FIGS. 5 and 6, the reinforcing frame 11 reinforces the direct backs of those located at the outermost periphery of the grid of the solder balls 301 arranged on the bottom surface of each of the packages 12 and 14 on the respective sides. In addition, the reinforcing frame 11 reinforces the direct backs of those located at the outermost periphery on two opposite sides of the grid of the solder balls 301 arranged on the bottom surface of the package 13 between the packages 12 and 14. The two opposite sides extend in the direction in which the packages 12 to 14 are aligned in substantially a straight line.

The reinforcing frame 11 is provided with eight screw holes 11a. Meanwhile, in the second mounting surface 10b of the circuit board 10 are formed through holes (not illustrated) through which screws pass. In the first embodiment, first, the reinforcing frame 11 is placed on the second mounting surface 10b so that it covers the portions corresponding to the positions of the solder balls 401 to 404 on the bottom surfaces of the packages 12 and 14 as well as the portions corresponding to the positions of the solder balls 401 and 403 on the bottom surface of the package 13. Next, the position of the reinforcing frame 11 is adjusted on the second mounting surface 10b to align the screw holes 11a of the reinforcing frame 11 with the through holes formed in the circuit board 10, respectively. Then, the screws are inserted through the screw holes 11a of the reinforcing frame 11 and are screwed into the through holes in the circuit board 10, respectively. Thus, the reinforcing frame 11 is attached to the circuit board 10. Incidentally, the reinforcing frame 11 of the first embodiment is made of, for example, metal with high hardness or resin.

As described above, according to the first embodiment, the reinforcing frame 11 reinforces the direct backs of those located at at least four corners of the grid of the solder balls 301 arranged on the bottom surface of each of the packages 12 to 14. This increase the rigidity of portions of the circuit board 10 to which the solder balls 301 are attached. Accordingly, even if an external force is applied vertically to the first mounting surface 10a of the circuit board 10, deformation does not occur in the circuit board 10 between portions corresponding to where the packages 12 to 14 are mounted and the reinforcing frame 11. Thus, the solder balls 301 can be prevented from being damaged due to deformation of the portions of the circuit board 10 to which the solder balls 301 are attached.

Besides, with conventional technologies, a reinforcing element is arranged with respect to each package mounted on a circuit board. Therefore, in the circuit board, the rigidity of a portion between packages (i.e., a portion not reinforced by the reinforcing element) is lower relative to that of a portion reinforced by the reinforcing element. As a result, the circuit board is locally bent or warped at the portion between packages.

On the other hand, according to the first embodiment, the reinforcing frame 11 reinforces where the packages 12 to 14 are mounted in an integrated manner. This increase the rigidity of portions of the circuit board 10 between the packages 12 to 14 as well. Thus, it is possible to reduce the warping of the circuit board 10 that occurs locally between one package and another, and thereby to reduce the deformation of the circuit board 10. Therefore, the solder balls 301 can be effectively prevented from being damaged due to deformation of the circuit board 10.

A modification of the first embodiment will be described. In the first embodiment, the reinforcing frame 11 is arranged to pass through portions on the second mounting surface 10b corresponding to the positions of those located at the outermost periphery of the grid of the solder balls 301 arranged on the bottom surface of each of the packages 12 and 14 on the respective sides. However, this is by way of example and not by way of limitation.

For example, the reinforcing frame may be arranged such that it passes through portions on the second mounting surface 10 b corresponding to the positions of those located at the outermost periphery of the grid of the solder balls 301 arranged on the bottom surface of a package not on the side. Alternatively, the reinforcing frame may be arranged such that it passes through portions on the second mounting surface 10b corresponding to the positions of those located at the outermost periphery of the grid of the solder balls 301 arranged on the bottom surface of at least either packages on the respective sides or a package between them.

FIG. 7 is a perspective view of a reinforcing frame 700 according to the modification. The reinforcing frame 700 illustrated in FIG. 7 is arranged such that it passes through portions on the second mounting surface 10b corresponding to the positions of the solder balls 401 to 404 (see FIG. 4) located at the outermost periphery of the grid of the solder balls 301 arranged on the bottom surface of the package 13 between the packages 12 and 14.

Besides, the reinforcing frame 700 is arranged such that it passes through portions on the second mounting surface 10b corresponding to the positions of the solder balls 401 and 403 located at the outermost periphery on at least two opposite sides of the grid of the solder balls 301 arranged on the bottom surface of each of the packages 12 and 14. The two opposite sides extend in the direction in which the packages 12 to 14 are aligned.

Further, in this modification, the reinforcing frame 700 is arranged such that it passes through portions on the second mounting surface 10b corresponding to the positions of the solder balls 404, in addition to the solder balls 401 and 403, on the package 12. Similarly, the reinforcing frame 700 is arranged such that it passes through portions on the second mounting surface 10b corresponding to the positions of the solder balls 402, in addition to the solder balls 401 and 403, on the package 14.

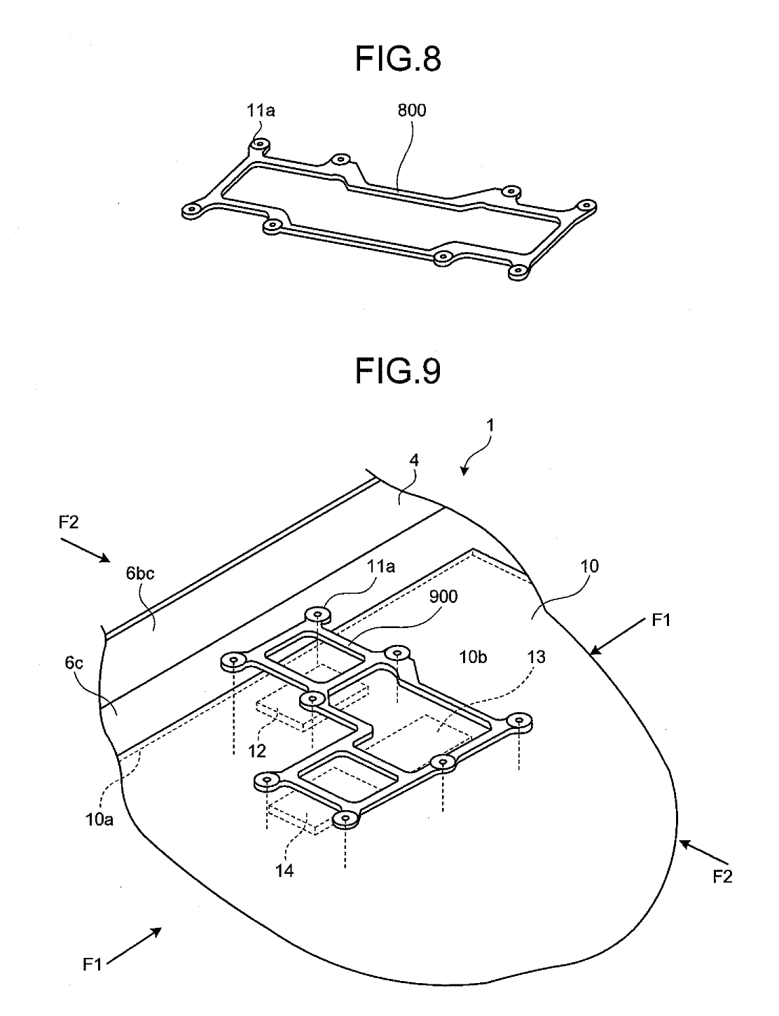

FIG. 8 is a perspective view of a reinforcing frame 800 according to another modification of the first embodiment. The reinforcing frame 800 illustrated in FIG. 8 is arranged such that it passes through portions on the second mounting surface 10b corresponding to the positions of the solder balls 401 and 403 located at the outermost periphery on at least two opposite sides of the grid of the solder balls 301 arranged on the bottom surface of each of the packages 12 to 14. The two opposite sides extend in the direction in which the packages 12 to 14 are aligned.

Further, in this modification, the reinforcing frame 800 is arranged such that it passes through portions on the second mounting surface 10b corresponding to the positions of the solder balls 404, in addition to the solder balls 401 and 403, on the package 12. Similarly, the reinforcing frame 800 is arranged such that it passes through portions on the second mounting surface 10b corresponding to the positions of the solder balls 402, in addition to the solder balls 401 and 403, on the package 14.

According to a second embodiment of the invention, an example is described in which the packages 12 to 14 are arranged in an L-shape on the circuit board 10 in the portable computer 1. In accordance with the arrangement of the packages 12 to 14, a reinforcing frame 900 of the second embodiment is different in form from the reinforcing frame 11 to achieve the same effect as in the first embodiment. Otherwise, the portable computer of the second embodiment is basically similar to the portable computer 1 of the first embodiment, and thus its description will not be repeated.

FIG. 9 is a schematic diagram of the inside of the housing of the portable computer 1 according to the second embodiment. On the first mounting surface 10a of the circuit board 10, the packages 12 to 14 are arranged in an L-shape.

The reinforcing frame 900 is arranged such that it passes through portions on the second mounting surface 10b corresponding to the positions of the solder balls 401 and 402 (see FIG. 4) among the solder balls 301 arranged in a grid on the bottom surface of the package 13 at the corner of the L-shape formed by the packages 12 to 14. The solder balls 401 and 402 are located at the outermost periphery on at least two adjacent sides of the grid of the solder balls 301. The two adjacent sides extend substantially in parallel with the bend of the L shape formed by the packages 12 to 14. Further, the reinforcing frame 900 is arranged such that it passes through portions on the second mounting surface 10b corresponding to the positions of solder balls located at the corner of the package 13 diagonally opposite the corner of the L shape.

In addition, the reinforcing frame 900 is arranged such that it passes through portions on the second mounting surface 10b corresponding to the positions of the solder balls 401 to 404 located at the outermost periphery of the grid of the solder balls 301 arranged on the bottom surface of each of the packages 12 and 14 on the respective sides.

In the second embodiment, the reinforcing frame 900 reinforces the direct backs of those located at the outermost periphery of the grid of the solder balls 301 arranged on the bottom surface of each of the packages 12 and 14 on the respective sides. However, this is by way of example and not by way of limitation. The reinforcing frame 900 is only required to reinforce the direct backs of positions where those located at four corners on the outermost periphery of the grid of the solder balls 301 are attached to the circuit board 10.

For example, the reinforcing frame 900 may be arranged such that it passes through portions on the second mounting surface 10b corresponding to the positions of the solder balls 401 to 404 located at the outermost periphery of the grid of the solder balls 301 arranged on the bottom surface of the package 13 not on the side, but at the corner.

As described above, according to the second embodiment, the reinforcing frame 900 is arranged to cover portions corresponding to the positions of those located at at least four corners of the grid of the solder balls 301 on the bottom surface of each of the packages 12 to 14 arranged in an L-shape. Thus, the same effect as in the first embodiment can be achieved.

Moreover, the reinforcing frame 900 reinforces where the packages 12 to 14 are mounted in an integrated manner. This increase the rigidity of portions of the circuit board 10 between one package and another as well. As a result, the same effect as in the first embodiment can also be achieved.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device comprising:
a housing;
a circuit board in the housing, the circuit board comprising a first surface and a second surface on a reverse side of the first surface;
a plurality of surface-mountable electronic components, each comprising a surface comprising bumps on the surface, the surface-mountable electronic components on the first surface via the bumps; and
a reinforcing frame on the second surface and configured to cover portions corresponding to positions of bumps located at four corners, at least, on the surface of each of the surface-mountable electronic components mounted on the first surface.

2. The electronic device of claim 1, wherein the reinforcing frame is configured to cover portions on the second surface corresponding to positions of bumps located at outermost periphery and on two opposite sides of the bumps on the surface of each of the surface-mountable electronic components.

3. The electronic device of claim 1, wherein
the surface-mountable electronic components are linearly mounted on the first surface, and
the reinforcing frame is configured to cover portions on the second surface corresponding to positions of bumps located at outermost periphery of the bumps on the surface of at least one of an peripheral portion of a surface-mountable electronic component and a non-peripheral portion of surface-mountable electronic component.

4. The electronic device of claim 1, wherein the surface-mountable electronic components are aligned in substantially a straight line on the first surface.

5. The electronic device of claim 1, wherein the surface-mountable electronic components are located in an L-shape on the first surface.

6. The electronic device of claim 1, wherein the bumps are solder bumps.
